(19) United States
(12) Patent Application Publication
(10) Pub. No.: US 2006/0225782 A1
(43) Pub. Date: Oct. 12, 2006

(54) Photovoltaic cells having a thermoelectric material

(76) Inventors: Howard Berke, Hollis, NH (US); Russell Gaudiana, Merrimack, NH (US)

Correspondence Address: FISH & RICHARDSON PC, P.O. BOX 1022, MINNEAPOLIS, MN, 55440-1022, US

(21) Appl. No.: 11/385,304

(22) Filed: Mar. 21, 2006

Related U.S. Application Data
(60) Provisional application No. 60/664,161, filed on Mar. 21, 2005.

(51) Int. Cl. H01L 31/00; H02N 6/00; H01L 35/30

(52) U.S. Cl. 136/252; 136/244; 136/205

(57) ABSTRACT

Photovoltaic cells having a thermoelectric material, as well as related systems, components, and methods are disclosed.

### CROSS REFERENCE TO RELATED APPLICATION

Pursuant to 35 U.S.C. § 119(e), this application claims priority to U.S. Provisional Application Ser. No. 60/664,161, filed Mar. 21, 2005, the contents of which are hereby incorporated by reference.

### TECHNICAL FIELD

This disclosure relates to photovoltaic cells having a thermoelectric material, as well as related systems, components, and methods.

### BACKGROUND

Photovoltaic cells, also called solar cells, can convert light, such as sunlight, into electrical energy. A typical photovoltaic cell includes a layer of a photoactive material disposed between a cathode and an anode. When incident light excites the photoactive material, electrons are released. The released electrons are captured in the form of electrical energy within the electric circuit created between the cathode and the anode.

In one type of photovoltaic cell, commonly called a dye-sensitized solar cell (DSSC), the photoactive material typically includes a semiconductor material (such as titania) and a photosensitizing agent (such as a dye). In general, the dye is capable of absorbing photons within a wavelength range of operation (e.g., within the solar spectrum).

In another type of photovoltaic cell, commonly referred to as a polymer thin film cell, the photoactive material used generally has two components, an electron acceptor and an electron donor. The electron donor can be a p-type polymeric conductor material, such as, poly(phenylene vinylene) or poly(3-hexylthiophene). The electron acceptor can be a nanoparticulate material, such as, a derivative of fullerene (e.g., 1-(3-methoxy carbonyl)-propyl-1-1-phenyl-(6,6) C61, known as PCBM).

Photovoltaic cells can be electrically connected in series and/or in parallel to create a photovoltaic module. Typically, two photovoltaic cells are connected in parallel by electrically connecting the cathode of one cell with the cathode of the other cell, and the anode of one cell with the anode of the other cell. In general, two photovoltaic cells are connected in series by electrically connecting the anode of one cell with the cathode of the other cell.

### SUMMARY

This disclosure relates to photovoltaic cells having a thermoelectric material, as well as related systems, components, and methods.

In one aspect, this invention features a photovoltaic cell that includes a substrate; a photoactive material supported by the substrate; and a thermoelectric material. The substrate is between the photoactive material and the thermoelectric material.

In another aspect, this invention features a photovoltaic module that includes a first photovoltaic cell and a second photovoltaic cell. The first photovoltaic cell includes a substrate, a photoactive material supported by the substrate, and a thermoelectric material, in which the substrate is between the photoactive material and the thermoelectric material. The first and second photovoltaic cells are electrically connected.

In a further aspect, the invention features a photovoltaic cell that includes a photoactive material and a thermoelectric material, where the thermoelectric material is configured to be electrically connected to a load.

In another aspect, the invention features a system that includes a photovoltaic cell and a load. The photovoltaic cell includes a photoactive material and a thermoelectric material, where the load is electrically connected to the thermoelectric material.

In a further aspect, the invention features a photovoltaic cell that includes a photoactive material and a thermoelectric material, provided that the thermoelectric material is not poly(3-hexylthiophene).

In another aspect, the invention features a photovoltaic cell that includes a photoactive material and a thermoelectric material that is electrically isolated from the photoactive material.

Embodiments can include one or more of the following features.

The thermoelectric material can include a polymer selected from the group consisting of polythiophenes, polyanilines, polysulfones, polysiloxanes, poly(carbozylenevinylene)s, and combinations thereof. In some embodiments, the thermoelectric material includes a substituted polythiophene, such as poly(3-hexylthiophene), poly(3-octylthiophene), or poly(3-dodecylthiophene).

The thermoelectric material can have a Seebeck coefficient at least about 500 μV/K (e.g., at least about 1 mV/K or at least about 5 mV/K).

The photoactive material can include an electron acceptor material. In some embodiments, the electron acceptor material includes a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof. In certain embodiments, the electron acceptor material includes a fullerene (e.g., a substituted fullerene).

The photoactive material can include an electron donor material. In some embodiments, the electron donor material includes a polymer selected from the group consisting of polyacetylenes, polyanilines, polyphenylenes, poly(p-phenylene vinylene)s, polythienylvinylenes, polythiophenes, polyporphyrins, porphyrinic macrocycles, polymetallocenes, polyisothianaphthalenes, polyphthalocyanines, discotic liquid crystal polymers, and combinations thereof.

The photactive material can include inorganic nanoparticles. The inorganic nanoparticles can include a compound selected from the group consisting of titanium oxide, zirconium oxide, zinc oxide, tungsten oxide, niobium oxide, lanthanum oxide, tin oxide, terbium oxide, tantalum oxide, indium phosphide, cadmium selenide, lead sulphide, and combinations thereof.

The photoactive material can include a dye. In some embodiments, the dye can include a compound selected from the group consisting of cyanines, merocyanines, phthalocyanines, pyrroles, xanthines, and combinations thereof. In certain embodiments, the photoactive material can include dye-sensitized interconnected inorganic nanoparticles.

The photovoltaic cell can include two electrodes. In some embodiments, at least one of the electrodes includes ITO, tin oxide, or fluorine-doped tin oxide.

The substrate can be a flexible substrate. In some embodiments, the substrate includes a polymer selected from a group consisting of polyethylene naphthalates, polyethylene terephthalates, polyethyelenes, polypropylenes, polyamides, polymethyl methacrylate, polycarbonates, polyurethanes, and combinations thereof.

The photovoltaic cell can include a silicon solar cell, a CIGS solar cell, a CIS solar cell, a dye-sensitized solar cell, a polymer solar cell, or a hybrid solar cell.

The first and second photovoltaic cells can be electrically connected in series or in parallel.

Embodiments can provide one or more of the following advantages.

In some embodiments, the thermoelectric material in a photovoltaic cell can generate electric energy from solar energy not absorbed by the photovoltaic cell but irradiated as heat, thereby increasing the efficiency of the photovoltaic cell.

Other features and advantages of the invention will be apparent from the description, drawings, and claims.

### DESCRIPTION OF DRAWINGS

FIG. 1 is a cross-sectional view of a DSSC.

FIG. 2 is a cross-sectional view of a polymer photovoltaic cell.

FIG. 3 is a schematic of a system containing multiple photovoltaic cells electrically connected in series.

FIG. 4 is a schematic of a system containing multiple photovoltaic cells electrically connected in parallel.

Like reference symbols in the various drawings indicate like elements.

### DETAILED DESCRIPTION

In general, the description relates to photovoltaic cells having a thermoelectric material. Embodiments of such cells are described below.

DSSCs

FIG. 1 is a cross-sectional view of a DSSC 100 including substrates 110 and 170, electrically conductive layers (electrodes) 120 and 160, a catalyst layer 130, a charge carrier layer 140, a photoactive layer 150, and a thermoelectric layer 180. DSSC 110 and the thermoelectric layer 180 is electrically connected to an external load 190.

Thermoelectric layer 180 includes a thermoelectric material. In general, a thermoelectric material is a material capable of generating electricity from a temperature gradient between two ends of the material. Exemplary thermoelectric materials include polythiophenes (e.g., substituted polythiophenes), polyanilines, polysulfones (e.g., chelates containing polysulfones), polysiloxanes (e.g., chelates containing polysiloxanes), polycarbozylenevinylenes (e.g., 3,6-substituted polycarbozylenevinylenes), and combinations thereof. For example, a thermoelectric material can be poly(3-hexylthiophene), poly(3-octylthiophene), or poly(3-dodecylthiophene).

In some embodiments, the thermoelectric material can have a Seebeck coefficient at least about 500 μV/K (e.g., at least about 1 mV/K or at least about 5 mV/K). As used herein, the “Seebeck coefficient” refers to the ratio between the electric field and the temperature gradient (or the ratio between the voltage difference and temperature difference) between two ends of a thermoelectric material.

The thermoelectric material can be applied onto a substrate via a solution coating process (e.g., such as slot coating, spin coating or gravure coating). The thermoelectric material can be applied on a substrate of a photovoltaic cell directly, or can be applied first onto a support, which is in turn attached to a substrate of a photovoltaic cell.

Without wishing to be bound by theory, it is believed that thermoelectric layer 180 can convert heat irradiated from other components of photovoltaic cell 100 to electricity. For example, as shown in FIG. 1, when the thermoelectric material is attached to the back of a photovoltaic cell, heat irradiated from the photovoltaic cell generates a temperature gradient between two ends of the thermoelectric material. The temperature gradient results in thermal diffusion of electrons (or holes), thereby producing an electric current in the thermoelectric material. The electric current is then provided to the external load.

Other components of a DSSC are described below.

Photoactive layer 150 generally includes one or more dyes and a semiconductor material associated with the dye.

Examples of dyes include black dyes (e.g., tris(isothiocyanato)-ruthenium (II)-2,2′:6′,2″-terpyridine-4,4′,4″-tricarboxylic acid, tris-tetrabutylammonium salt), orange dyes (e.g., tris(2,2′-bipyridyl-4,4′-dicarboxylato) ruthenium (II) dichloride, purple dyes (e.g., cis-bis(isothiocyanato)bis-(2,2′-bipyridyl-4,4′-dicarboxylato)-ruthenium (II)), red dyes (e.g., an eosin), green dyes (e.g., a merocyanine) and blue dyes (e.g., a cyanine). Examples of additional dyes include anthocyanines, porphyrins, phthalocyanines, squarates, and certain metal-containing dyes.

In some embodiments, photoactive layer 150 can include multiple different dyes that form a pattern. Examples of patterns include camouflage patterns, roof tile patterns and shingle patterns. In some embodiments, the pattern can define the pattern of the housing a portable electronic device (e.g., a laptop computer, a cell phone). In certain embodiments, the pattern provided by the photovoltaic cell can define the pattern on the body of an automobile. Patterned photovoltaic cells are disclosed, for example, in co-pending and commonly owned U.S. Ser. No. 11/311,805, which is hereby incorporated by reference.

Examples of semiconductor materials include materials having the formula MₓO_{y}, where M can be, for example, titanium, zirconium, zinc, tungsten, niobium, lanthanum, tantalum, terbium, or tin, and x and y are integers greater than zero. Other suitable materials include phosphides, sulfides, selenides, tellurides, niobates, and oxides of titanium, zirconium, tungsten, niobium, lanthanum, tantalum, terbium, tin, indium, lead, potassium, or combinations thereof. For example, TiO₂, SrTiO₃, CaTiO₃, ZrO₂, WO₃, La₂O₃, Nb₂O₅, SnO₂, sodium titanate, indium phosphide, lead sulphide, cadmium selenide (CdSe), cadmium sulphides, and potassium niobate may be suitable materials.

Typically, the semiconductor material contained within photoactive layer 150 is in the form of nanoparticles. In some embodiments, the nanoparticles have an average size between about two nm and about 100 nm (e.g., between about 10 nm and 40 nm, such as about 20 nm). Examples of nanoparticle semiconductor materials are disclosed, for example, in co-pending and commonly owned U.S. Ser. No. 10/351,249, which is hereby incorporated by reference.

The nanoparticles can be interconnected, for example, by high temperature sintering, or by a reactive linking agent.

In certain embodiments, the linking agent can be a non-polymeric compound. The linking agent can exhibit similar electronic conductivity as the semiconductor particles. For example, for TiO₂ particles, the agent can include Ti—O bonds, such as those present in titanium alkoxides. Without wishing to be bound by theory, it is believed that titanium tetraalkoxide particles can react with each other, with TiO₂ particles, and with a conductive coating (not shown) on a substrate, to form titanium oxide bridges that connect the particles with each other and with the conductive coating. As a result, the cross-linking agent enhances the stability and integrity of the semiconductor layer. The cross-linking agent can include, for example, an organometallic species such as a metal alkoxide, a metal acetate, or a metal halide. In some embodiments, the cross-linking agent can include a different metal than the metal in the semiconductor. In an exemplary cross-linking step, a cross-linking agent solution is prepared by mixing a sol-gel precursor agent, e.g., a titanium tetra-alkoxide such as titanium tetrabutoxide, with a solvent, such as ethanol, propanol, butanol, or higher primary, secondary, or tertiary alcohols, in a weight ratio of 0-100%, e.g., about 5 to about 25%, or about 20%. Generally, the solvent can be any material that is stable with respect to the precursor agent, e.g., does not react with the agent to form metal oxides (e.g. TiO₂). The solvent preferably is substantially free of water, which can cause precipitation of TiO₂. Such linking agents are disclosed, for example, in published U.S. Patent Application 2003-0056821, which is hereby incorporated by reference.

In some embodiments, a linking agent can be a polymeric linking agent, such as poly(n-butyl titanate). Examples of polymeric linking agents are disclosed, for example, in co-pending and commonly owned U.S. Ser. No. 10/350,913, which is hereby incorporated by reference.

Linking agents can allow for the fabrication of an interconnected nanoparticle layer at relatively low temperatures (e.g., less than about 300° C.) and in some embodiments at room temperature. The relatively low temperature interconnection process may be amenable to continuous (e.g., roll-to-roll) manufacturing processes using polymer substrates.

The interconnected nanoparticles are generally photosensitized by the dye(s). The dyes facilitate conversion of incident light into electricity to produce the desired photovoltaic effect. It is believed that a dye absorbs incident light resulting in the excitation of electrons in the dye. The energy of the excited electrons is then transferred from the excitation levels of the dye into a conduction band of the interconnected nanoparticles. This electron transfer results in an effective separation of charge and the desired photovoltaic effect. Accordingly, the electrons in the conduction band of the interconnected nanoparticles are made available to drive an external load.

The dye(s) can be sorbed (e.g., chemisorbed and/or physisorbed) on the nanoparticles. A dye can be selected, for example, based on its ability to absorb photons in a wavelength range of operation (e.g., within the visible spectrum), its ability to produce free electrons (or electron holes) in a conduction band of the nanoparticles, its effectiveness in complexing with or sorbing to the nanoparticles, and/or its color.

In some embodiments, photoactive layer 150 can further include one or more co-sensitizers that adsorb with a sensitizing dye to the surface of an interconnected semiconductor oxide nanoparticle material, which can increase the efficiency of a DSSC (e.g., by improving charge transfer efficiency and/or reducing back transfer of electrons from the interconnected semiconductor oxide nanoparticle material to the sensitizing dye). The sensitizing dye and the co-sensitizer may be added together or separately when forming the photosensitized interconnected nanoparticle material. The co-sensitizer can donate electrons to an acceptor to form stable cation radicals, which can enhance the efficiency of charge transfer from the sensitizing dye to the semiconductor oxide nanoparticle material and/or can reduce back electron transfer to the sensitizing dye or co-sensitizer. The co-sensitizer can include (1) conjugation of the free electron pair on a nitrogen atom with the hybridized orbitals of the aromatic rings to which the nitrogen atom is bonded and, subsequent to electron transfer, the resulting resonance stabilization of the cation radicals by these hybridized orbitals; and/or (2) a coordinating group, such as a carboxy or a phosphate, the function of which is to anchor the co-sensitizer to the semiconductor oxide. Examples of suitable co-sensitizers include aromatic amines (e.g., triphenylamine and its derivatives), carbazoles, and other fused-ring analogues. Examples of photoactive layers including co-sensitizers are disclosed in co-pending and commonly owned U.S. Ser. No. 10/350,919, which is hereby incorporated by reference.

In some embodiments, photoactive layer 150 can further include macroparticles of the semiconductor material, where at least some of the semiconductor macroparticles are chemically bonded to each other, and at least some of the semiconductor nanoparticles are bonded to semiconductor macroparticles. The dye(s) are sorbed (e.g., chemisorbed and/or physisorbed) on the semiconductor material. Macroparticles refers to a collection of particles having an average particle size of at least about 100 nanometers (e.g., at least about 150 nanometers, at least about 200 nanometers, at least about 250 nanometers). Examples of photovoltaic cells including macroparticles in the photoactive layer are disclosed in co-pending and commonly owned U.S. Ser. No. 11/179,976, which is hereby incorporated by reference.

In certain embodiments, a DSSC can include a coating that can enhance the adhesion of a photovoltaic material to a base material (e.g., using relatively low process temperatures, such as less than about 300° C.). Such photovoltaic cells and methods are disclosed, for example, in co-pending and commonly owned U.S. Ser. No. 10/351,260, which is hereby incorporated by reference.

The composition and thickness of electrically conductive layer 120 is generally selected based on desired electrical conductivity, optical properties, and/or mechanical properties of the layer. In some embodiments, layer 120 is transparent. Examples of transparent materials suitable for forming such a layer include certain metal oxides, such as indium tin oxide (ITO), tin oxide, and a fluorine-doped tin oxide. In some embodiments, electrically conductive layer 120 can be formed of a foil (e.g., a titanium foil). Electrically conductive layer 120 can be, for example, between about 100 nm and 500 nm thick (e.g., between about 150 nm and 300 nm thick).

In certain embodiments, electrically conductive layer 120 can be opaque (i.e., can transmit less than about 10% of the visible spectrum energy incident thereon). For example, layer 120 can be formed from a continuous layer of an opaque metal, such as copper, aluminum, indium, or gold. In some embodiments, an electrically conductive layer can have an interconnected nanoparticle material formed thereon. Such layers can be, for example, in the form of strips (e.g., having a controlled size and relative spacing, between first and second substrates). Examples of such DSSCs are disclosed in co-pending and commonly owned U.S. Ser. No. 10/351,251, which is hereby incorporated by reference.

In some embodiments, electrically conductive layer 120 can include a discontinuous layer of an electrically conductive material. For example, electrically conductive layer 120 can include an electrically conducting mesh. Suitable mesh materials include metals, such as palladium, titanium, platinum, stainless steels and alloys thereof. In some embodiments, the mesh material includes a metal wire. The electrically conductive mesh material can also include an electrically insulating material that has been coated with an electrically conducting material, such as a metal. The electrically insulating material can include a fiber, such as a textile fiber or monofilament. Examples of fibers include synthetic polymeric fibers (e.g., nylons) and natural fibers (e.g., flax, cotton, wool, and silk). The mesh electrically conductive layer can be flexible to facilitate, for example, formation of the DSSC by a continuous manufacturing process. Photovoltaic cells having mesh electrically conductive layers are disclosed, for example, in co-pending and commonly owned U.S. Ser. Nos. 10/395,823, 10/723,554 and 10/494,560, each of which is hereby incorporated by reference.

The mesh electrically conductive layer may take a wide variety of forms with respect to, for example, wire (or fiber) diameters and mesh densities (i.e., the number of wires (or fibers) per unit area of the mesh). The mesh can be, for example, regular or irregular, with any number of opening shapes. Mesh form factors (e.g., wire diameter and mesh density) can be chosen, for example, based on the conductivity of the wire (or fibers) of the mesh, the desired optical transmissivity, flexibility, and/or mechanical strength. Typically, the mesh electrically conductive layer includes a wire (or fiber) mesh with an average wire (or fiber) diameter in the range from about one micron to about 400 microns, and an average open area between wires (or fibers) in the range from about 60% to about 95%.

Catalyst layer 130 is generally formed of a material that can catalyze a redox reaction in the charge carrier layer positioned below. Examples of materials from which catalyst layer can be formed include platinum and polymers, such as polythiophenes, polypyrroles, polyanilines and their derivatives. Examples of polythiophene derivatives include poly(3,4-ethylenedioxythiophene) (“PEDOT”), poly(3-butylthiophene), poly[3-(4-octylphenyl)thiophene], poly(thieno[3,4-b]thiophene) (“PT34bT”), and poly(thieno[3,4-b]thiophene-co-3,4-ethylenedioxythiophene) (“PT34bT-PEDOT”). Examples of catalyst layers containing one or more polymers are disclosed in co-pending and commonly owned U.S. Ser. Nos. 10/897,268 and 60/637,844, both of which are hereby incorporated by reference.

Substrate 110 can be formed from a mechanically-flexible material (such as a flexible polymer) or a rigid material (such as a glass). A flexible material is a material capable of being bent without damage. Examples of flexible materials include polyethylene naphthalates (PEN), polyethylene terephthalates (PET), polyethyelenes, polypropylenes, polyamides, polymethylmethacrylate, polycarbonate, and/or polyurethanes. Flexible substrates can facilitate continuous manufacturing processes such as web-based coating and lamination. However, rigid substrate materials can also be used, such as those disclosed in co-pending and commonly owned U.S. Ser. No. 10/351,265, which is hereby incorporated by reference.

The thickness of substrate 110 can vary as desired. Typically, substrate thickness and type are selected to provide mechanical support sufficient for the DSSC to withstand the rigors of manufacturing, deployment, and use. Substrate 110 can have a thickness of from about six microns to about 5,000 microns (e.g., from about 6 microns to about 50 microns, from about 50 microns to about 5,000 microns, from about 100 microns to about 1,000 microns).

In embodiments where electrically conductive layer 120 is transparent, substrate 310 is formed from a transparent material. As referred to herein, a transparent material transmits at least about 60% (e.g., at least about 70%, at least about 75%, at least about 80%, or at least about 85%) of incident energy at a wavelength or a range of wavelengths used during operation of the photovoltaic cell. As an example, substrate 110 can be formed from a transparent glass or polymer, such as a silica-based glass or a polymer, such as those listed above. In such embodiments, electrically conductive layer 120 may also be transparent.

Substrate 170 and electrically conductive layer 160 can be the same as described above regarding substrate 110 and electrically conductive layer 120, respectively. For example, substrate 170 can be formed from the same materials and can have the same thickness as substrate 110. In some embodiments however, it may be desirable for substrate 170 to be different from 110 in one or more aspects. For example, where the DSSC is manufactured using a process that places different stresses on the different substrates, it may be desirable for substrate 170 to be more or less mechanically robust than substrate 110. Accordingly, substrate 170 may be formed from a different material, or may have a different thickness than substrate 110. Furthermore, in embodiments where only one substrate is exposed to an illumination source during use, it is not necessary for both substrates and/or electrically conducting layers to be transparent. Accordingly, one of substrates and/or corresponding electrically conducting layer can be opaque.

Generally, charge carrier layer 140 includes a material that facilitates the transfer of electrical charge from a ground potential or a current source to photoactive layer 150. A general class of suitable charge carrier materials include solvent-based liquid electrolytes, polyelectrolytes, polymeric electrolytes, solid electrolytes, n-type and p-type transporting materials (e.g., conducting polymers) and gel electrolytes. Examples of gel electrolytes are disclosed in co-pending and commonly owned U.S. Ser. No. 10/350,912, which is hereby incorporated by reference. Other choices for charge carrier media are possible. For example, the charge carrier layer can include a lithium salt that has the formula LiX, where X is an iodide, bromide, chloride, perchlorate, thiocyanate, trifluoromethyl sulfonate, or hexafluorophosphate.

The charge carrier media typically includes a redox system. Suitable redox systems may include organic and/or inorganic redox systems. Examples of such systems include cerium(III) sulphate/cerium(IV), sodium bromide/bromine, lithium iodide/iodine, Fe²⁺/Fe³⁺, Co²⁺/Co³⁺, and viologens. Furthermore, an electrolyte solution may have the formula MᵢXⱼ, where i and j are greater than or equal to one, where X is an anion, and M is lithium, copper, barium, zinc, nickel, a lanthanide, cobalt, calcium, aluminum, or magnesium. Suitable anions include chloride, perchlorate, thiocyanate, trifluoromethyl sulfonate, and hexafluorophosphate.

In some embodiments, the charge carrier media includes a polymeric electrolyte. For example, the polymeric electrolyte can include poly(vinyl imidazolium halide) and lithium iodide and/or polyvinyl pyridinium salts. In certain embodiments, the charge carrier media can include a solid electrolyte, such as lithium iodide, pyridimum iodide, and/or substituted imidazolium iodide.

The charge carrier media can include various types of polymeric polyelectrolytes. For example, suitable polyelectrolytes can include between about 5% and about 95% (e.g., 5-60%, 5-40%, or 5-20%) by weight of a polymer, e.g., an ion-conducting polymer, and about 5% to about 95% (e.g., about 35-95%, 60-95%, or 80-95%) by weight of a plasticizer, about 0.05 M to about 10 M of a redox electrolyte of organic or inorganic iodides (e.g., about 0.05-2 M, 0.05-1 M, or 0.05-0.5 M), and about 0.01 M to about 1 M (e.g., about 0.05-0.5 M, 0.05-0.2 M, or 0.05-0.1 M) of iodine. The ion-conducting polymer may include, for example, polyethylene oxide (PEO), polyacrylonitrile (PAN), polymethylmethacrylate (PMMA), polyethers, and polyphenols. Examples of suitable plasticizers include ethyl carbonate, propylene carbonate, mixtures of carbonates, organic phosphates, butyrolactone, and dialkylphthalates.

In some embodiments, charge carrier layer 140 can include one or more zwitterionic compounds. Charge carrier layers including one or more zwitterionic compounds are disclosed, for example, in co-pending and commonly owned U.S. Ser. No. 11/000,276, which is hereby incorporated by reference.

In general, during operation of a DSSC, incident light (e.g., sunlight) excites a dye in photoactive layer. The excited dye then injects electrons into the conduction band of the semiconductor material in photoactive layer, which leaves the dye oxidized. The injected electrons flow through the semiconductor material, to the anode, then to an external load. After flowing through the external load, the electrons flow to cathode, then to the catalyst layer, where the electrons reduce the electrolyte. The reduced electrolyte can then reduce the oxidized dye molecules in the photoactive layer back to their neutral state. The electrolyte can act as a redox mediator to control the flow of electrons from the cathode to the anode. This cycle of excitation, oxidation, and reduction is repeated to provide continuous electrical energy to the external load.

A DSSC can be manufactured by a roll-to-roll process, such as those disclosed in co-pending and commonly owned U.S. Ser. No. 11/134,921, U.S. Ser. No. 10/395,823, and U.S. Ser. No. 11/127,439, which are hereby incorporated by reference.

Polymer Photovoltaic Cells

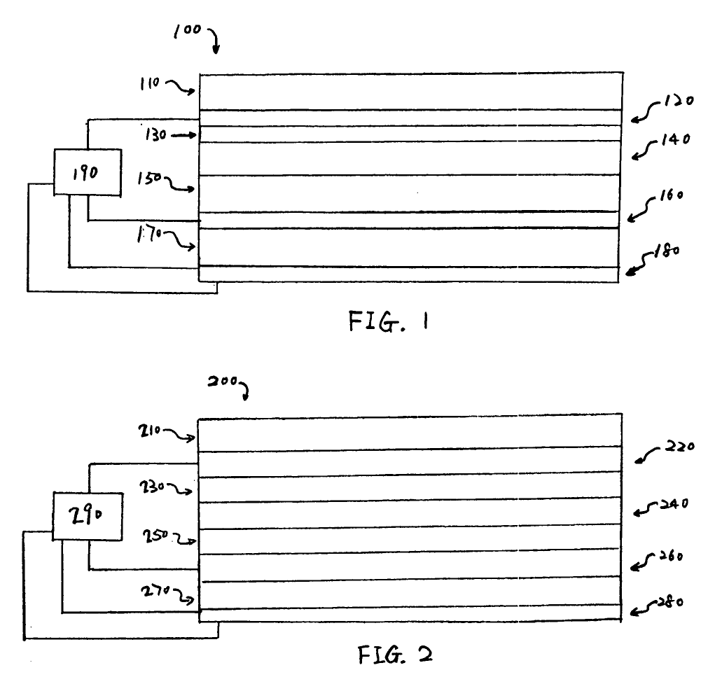

While DSSCs are described above, a layer of thermoelectric materials can also be incorporated in a polymer photovoltaic cell. For example, FIG. 2 shows a polymer photovoltaic cell 200 that includes substrates 210 and 270, electrically conductive layers (electrodes) 220 and 260, a hole blocking layer 230, a photoactive layer 240, a hole carrier layer 250, and a thermoelectric layer 280. Cell 200 and thermoelectric layer 280 are electrically connected to external load 290. Thermoelectric layer 280 can include the same thermoelectric materials as those described in a DSSC. Without wishing to be bound by theory, it is believed that thermoelectric layer 280 can convert heat irradiated from other components of photovoltaic cell 200 to electricity.

In general, substrate 210 and/or substrate 270 can be as described above with respect to the substrates in a DSSC. Exemplary materials include polyethylene tereplithalate (PET), polyethylene naphthalate (PEN), or a polyimide. An example of a polyimide is a KAPTON® polyimide film (available from E. I. du Pont de Nemours and Co.).

Generally, electrically conductive layer 220 and/or electrically conductive layer 260 can be as described with respect to the electrically conductive layers in a DSSC.

Hole blocking layer 230 is generally formed of a material that, at the thickness used in photovoltaic cell 200, transports electrons to electrically conductive layer 220 and substantially blocks the transport of holes to electrically conductive layer 220. Examples of materials from which layer 230 can be formed include LiF, metal oxides (e.g., zinc oxide, titanium oxide) and combinations thereof. While the thickness of layer 230 can generally be varied as desired, this thickness is typically at least 0.02 micron (e.g., at least about 0.03 micron, at least about 0.04 micron, at least about 0.05 micron) thick and/or at most about 0.5 micron (e.g., at most about 0.4 micron, at most about 0.3 micron, at most about 0.2 micron, at most about 0.1 micron) thick. In some embodiments, this distance is from 0.01 micron to about 0.5 micron. In some embodiments, layer 230 is a thin (e.g., at most about 5 nanometers) LiF layer. Such layers are disclosed, for example, in co-pending and commonly owned U.S. Ser. No. 10/258,708, which is hereby incorporated by reference.

Hole carrier layer 250 is generally formed of a material that, at the thickness used in photovoltaic cell 200, transports holes to electrically conductive layer 260 and substantially blocks the transport of electrons to electrically conductive layer 260. Examples of materials from which layer 250 can be formed include polythiophenes (e.g., PEDOT), polyanilines, polyvinylcarbazoles, polyphenylenes, polyphenylvinylenes, polysilanes, polythienylenevinylenes, polyisothianaphthanenes and combinations thereof. While the thickness of layer 250 can generally be varied as desired, this thickness is typically at least 0.01 micron (e.g., at least about 0.05 micron, at least about 0.1 micron, at least about 0.2 micron, at least about 0.3 micron, at least about 0.5 micron) and/or at most about five microns (e.g., at most about three microns, at most about two microns, at most about one micron). In some embodiments, this distance is from 0.01 micron to about 0.5 micron.

Photoactive layer 240 generally includes an electron acceptor material and an electron donor material.

Examples of electron acceptor materials include fullerenes, oxadiazoles, carbon nanorods, discotic liquid crystals, inorganic nanoparticles (e.g., nanoparticles formed of zinc oxide, tungsten oxide, indium phosphide, cadmium selenide and/or lead sulphide), inorganic nanorods (e.g., nanorods formed of zinc oxide, tungsten oxide, indium phosphide, cadmium selenide and/or lead sulphide), or polymers containing moieties capable of accepting electrons or forming stable anions (e.g., polymers containing CN groups, polymers containing CF₃ groups). In some embodiments, the electron acceptor material is a substituted fullerene (e.g., PCBM). In some embodiments, a substituted fillerene can include a fullerene, a pendant group (e.g., a cyclic ether such as epoxy, oxetane, or furan) and a linking group that spaces the pendant group apart from the fullerene. The pendant group is generally sufficiently reactive that the substituted fullerene may be reacted with another compound (e.g., another substituted fullerene) to prepare a reaction product. An example of such a substituted fullerene is C61-phenyl-butyric acid glycidol ester, known as PCBG. Photoactive layers including substituted fullerenes are disclosed, for example, in co-pending and commonly owned U.S. Ser. No. 11/141,979, which is hereby incorporated by reference. Combinations of electron acceptor materials can also be used.

Examples of electron donor materials include discotic liquid crystal polymers, polyacetylenes, polyanilines, polyphenylenes, poly(p-phenylene vinylene)s, polythienylvinylenes, polythiophenes, polyporphyrins, porphyrinic macrocycles, polymetallocenes, polyisothianaphthalenes, polyphthalocyanines, and polysilanes. In some embodiments, the electron donor material is poly(3-hexylthiophene) (P3HT). In certain embodiments, photoactive layer 240 can include a combination of electron donor materials.

In some embodiments, photoactive layer 240 includes an oriented electron donor material (e.g., a liquid crystal (LC) material), an electroactive polymeric binder carrier (e.g., a poly(3-hexylthiophene) material), and a plurality of nanocrystals (e.g., oriented nanorods including at least one of ZnO, WO₃, or TiO₂). The liquid crystal (LC) material can be, for example, a discotic nematic LC material, including a plurality of discotic mesogen units. Each unit can include a central group and a plurality of electroactive arms. The central group can include at least one aromatic ring (e.g., an anthracene group). Each electroactive arm can include a plurality of thiophene moieties and a plurality of alkyl moieties. Within the photoactive layer, the units can align in layers and columns. Electroactive arms of units in adjacent columns can interdigitate with one another to facilitate electron transfer between units. Also, the electroactive polymeric carrier can be distributed amongst the LC material to further facilitate electron transfer. The surface of each nanocrystal can include a plurality of electroactive surfactant groups to facilitate electron transfer from the LC material and polymeric carrier to the nanocrystals. Each surfactant group can include a plurality of thiophene groups. Each surfactant group can be bound to the nanocrystal via, for example, a phosphonic end-group. Each surfactant group can also include a plurality of alkyl moieties to enhance solubility of the nanocrystals in the photoactive layer. Examples of photovoltaic cells are disclosed in co-pending and commonly owned U.S. Ser. No. 60/664,336, which is hereby incorporated by reference.

In certain embodiments, the electron donor and electron acceptor materials in photoactive layer 240 can be selected so that the electron donor material, the electron acceptor material and their mixed phases have an average largest grain size of less than 500 nanometers in at least some sections of layer 240. In such embodiments, preparation of layer 240 can include using a dispersion agent (e.g., chlorobenzene) as a solvent for both the electron donor and the electron acceptor. Such photoactive layers are disclosed, for example, in co-pending and commonly owned U.S. Ser. No. 10/258,713, which is hereby incorporated by reference.

Generally, photoactive layer 240 is sufficiently thick to be relatively efficient at absorbing photons impinging thereon to form corresponding electrons and holes, and sufficiently thin to be relatively efficient at transporting the holes and electrons to the electrically conductive layers of the device. In certain embodiments, layer 240 is at least 0.05 micron (e.g., at least about 0.1 micron, at least about 0.2 micron, at least about 0.3 micron) thick and/or at most about one micron (e.g., at most about 0.5 micron, at most about 0.4 micron) thick. In some embodiments, layer 240 is from 0.1 micron to about 0.2 micron thick.

In some embodiments, the transparency of photoactive layer 240 can change as an electric field to which layer 240 is exposed changes. Such photovoltaic cells are disclosed, for example, in co-pending and commonly owned U.S. Ser. No. 10/486,116, which is hereby incorporated by reference.

In some embodiments, photovoltaic cell 200 can further include an additional layer (e.g., formed of a conjugated polymer, such as a doped poly(3-alkylthiophene)) between photoactive layer 240 and electrically conductive layer 220, and/or an additional layer (e.g., formed of a conjugated polymer) between photoactive layer 240 and electrically conductive layer 260. The additional layer(s) can have a band gap (e.g., achieved by appropriate doping) of 1.8 eV. Such photovoltaic cells are disclosed, for example, in U.S. Pat. No. 6,812,399, which is hereby incorporated by reference.

Optionally, photovoltaic cell 200 can further include a thin LiF layer between photoactive layer 240 and electrically conductive layer 260. Such layers are disclosed, for example, in co-pending and commonly owned U.S. Ser. No. 10/258,708, which is hereby incorporated by reference.

In some embodiments, photovoltaic cell 200 can be prepared as follows. Electrically conductive layer 220 is formed upon substrate 210 using conventional techniques. Electrically conductive layer 220 is configured to allow an electrical connection to be made with an external load. Layer 230 is formed upon electrically conductive layer 220 using, for example, a solution coating process (e.g., such as slot coating, spin coating or gravure coating). Photoactive layer 240 is formed upon layer 230 using, for example, a solution coating process. Layer 250 is formed on photoactive layer 240 using, for example, a solution coating process (e.g., such as slot coating, spin coating or gravure coating). Electrically conductive layer 220 is formed upon layer 250 using, for example, a vacuum coating process, such as evaporation or sputtering.

In certain embodiments, preparation of cell 200 can include a heat treatment above the glass transition temperature of the electron donor material for a predetermined treatment time. To increase efficiency, the heat treatment of the photovoltaic cell can be carried out for at least a portion of the treatment time under the influence of an electric field induced by a field voltage applied to the electrically conductive layers of the photovoltaic cell and exceeding the no-load voltage thereof. Such methods are disclosed, for example, in co-pending and commonly owned U.S. Ser. No. 10/509,935, which is hereby incorporated by reference.

Hybrid Cells

In some embodiments, a photovoltaic cell including a layer of a thermoelectric material can be a hybrid cell. For example, the photoactive material in such a cell can contain a dye-sensitized nanoparticles (e.g., titania) typically used in a DSSC and an electron donor material (e.g., P3HT) typically used in a polymer photovoltaic cell. Without wishing to bound by theory, it is believed that the electron donor material can replace the multi-component electrolyte used in a DSSC, thereby simplifying the manufacturing process and improving the reproducibility of a photovoltaic cell. Without wishing to be bound by theory, it is believed that the thermoelectric layer in a hybrid cell can convert heat irradiated from other components to electricity.

In some embodiments, a photovoltaic cell including a layer of a thermoelectric material can be a silicon solar cell, a CIS solar cell, or a CIGS solar cell. A silicon solar cell typically includes both p-type silicon and n-type silicon as the photoactive material. In general, either crystalline or amorphous silicon can be used in a silicon solar cell. A CIS solar cell generally includes a layer of copper indium diselenide (CIS) as a p-type semiconductor in the photoactive material. A CIGS solar cell generally includes copper indium gallium diselenide (CIGS) as a p-type semiconductor in the photoactive material. Without wishing to be bound by theory, it is believed that the thermoelectric layer in a photovoltaic cell described above can convert heat irradiated from other components to electricity.

While certain embodiments have been described, other embodiments are possible.

As an example, in general, the thermoelectric material can be disposed within a photovoltaic cell at any desired location. For example, in some embodiments, the thermoelectric material can be disposed between a substrate and the photoactive material. In some embodiments, the thermoelectric material is electrically isolated from the photoactive material.

As another example, in general, a photovoltaic cell may include multiple layers of thermoelectric material incorporated as desired in the photovoltaic cell. In embodiments in which a photovoltaic cell includes multiple layers of thermoelectric material, different layers of thermoelectric material may be formed of the same thermoelectric material or may be formed of different thermoelectric materials. In certain embodiments the thermoelectric material is configured to be electrically connected to an external load.

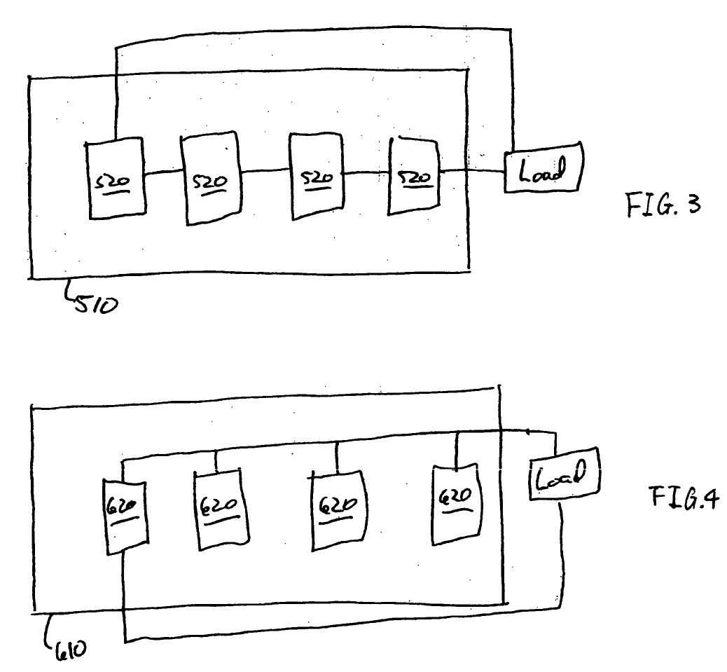

Further, multiple photovoltaic cells having a layer of a thermoelectric material can be electrically connected to form a photovoltaic system. As an example, FIG. 3 is a schematic of a photovoltaic system having a module 510 containing photovoltaic cells 520. Cells 520 are electrically connected in series, and the system is electrically connected to a load. As another example, FIG. 4 is a schematic of a photovoltaic system having a module 610 that contains photovoltaic cells 620. Cells 620 are electrically connected in parallel, and the system is electrically connected to a load. In some embodiments, some (e.g., all) of the photovoltaic cells in a photovoltaic system can have one or more common substrates. In certain embodiments, some photovoltaic cells in a photovoltaic system are electrically connected in series, and some of the photovoltaic cells in the photovoltaic system are electrically connected in parallel.

Other embodiments are in the claims.

What is claimed is:

1. A photovoltaic cell, comprising:
a substrate;
a photoactive material supported by the substrate; and
a thermoelectric material, wherein the substrate is between the photoactive material and the thermoelectric material.

2. The photovoltaic cell of claim 1, wherein the thermoelectric material comprises a polymer selected from the group consisting of polythiophenes, polyanilines, polysulfones, polysiloxanes, poly(carbozylenevinylene)s, and combinations thereof.

3. The photovoltaic cell of claim 2, wherein the thermoelectric material comprises a substituted polythiophene.

4. The photovoltaic cell of claim 3, wherein the substituted polythiophene comprises poly(3-hexylthiophene), poly(3-octylthiophene), or poly(3-dodecylthiophene).

5. The photovoltaic cell of claim 1, wherein the thermoelectric material has a Seebeck coefficient at least about 500 μV/K.

6. The photovoltaic cell of claim 1, wherein the thermoelectric material has a Seebeck coefficient at least about 1 mV/K.

7. The photovoltaic cell of claim 1, wherein the thermoelectric material has a Seebeck coefficient at least about 5 mV/K.

8. The photovoltaic cell of claim 1, wherein the photoactive material comprises an electron acceptor material.

9. The photovoltaic cell of claim 1, wherein the electron acceptor material comprises a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof.

10. The photovoltaic cell of claim 8, wherein the electron acceptor material comprises a fullerene.

11. The photovoltaic cell of claim 10, wherein the fullerene is a substituted fullerene.

12. The photovoltaic cell of claim 8, wherein the photoactive material further comprises an electron donor material.

13. The photovoltaic cell of claim 12, wherein the electron donor material comprises a polymer selected from the group consisting of polyacetylenes, polyanilines, polyphenylenes, poly(p-phenylene vinylene)s, polythienylvinylenes, polythiophenes, polyporphyrins, porphyrinic macrocycles, polymetallocenes, polyisothianaphthalenes, polyphthalocyanines, discotic liquid crystal polymers, and combinations thereof.

14. The photovoltaic cell of claim 1, wherein the photoactive material comprises inorganic nanoparticles.

15. The photovoltaic cell of claim 14, wherein the inorganic nanoparticles comprise a compound selected from the group consisting of titanium oxide, zirconium oxide, zinc oxide, tungsten oxide, niobium oxide, lanthanum oxide, tin oxide, terbium oxide, tantalum oxide, indium phosphide, cadmium selenide, lead sulphide, and combinations thereof.

16. The photovoltaic cell of claim 14, wherein the photoactive material further comprises a dye.

17. The photovoltaic cell of claim 16, wherein the dye comprises a compound selected from the group consisting of cyanines, merocyanines, phthalocyanines, pyrroles, xanthines, and combinations thereof.

18. The photovoltaic cell of claim 14, wherein the photoactive material comprises dye-sensitized interconnected inorganic nanoparticles.

19. The photovoltaic cell of claim 1, wherein the photovoltaic cell comprises two electrodes, at least one of the electrodes comprising ITO, tin oxide, or fluorine-doped tin oxide.

20. The photovoltaic cell of claim 1, wherein the substrate is a flexible substrate.

21. The photovoltaic cell of claim 1, wherein the substrate comprises a polymer selected from a group consisting of polyethylene naphthalates, polyethylene terephthalates, polyethyelenes, polypropylenes, polyamides, polymethyl methacrylate, polycarbonates, polyurethanes, and combinations thereof.

22. The photovoltaic cell of claim 1, wherein the photovoltaic cell comprises a silicon solar cell, a CIGS solar cell, a CIS solar cell, a dye-sensitized solar cell, a polymer solar cell, or a hybrid solar cell.

23. A photovoltaic module, comprising:
a first photovoltaic cell comprising a substrate, a photoactive material supported by the substrate, and a thermoelectric material, wherein the substrate is between the photoactive material and the thermoelectric material; and
a second photovoltaic cell;
wherein the first and second photovoltaic cells are electrically connected.

24. The photovoltaic module of claim 23, wherein the first and second photovoltaic cells are electrically connected in series.

25. The photovoltaic module of claim 23, wherein the first and second photovoltaic cells are electrically connected in parallel.

26. A photovoltaic cell, comprising:
a photoactive material; and
a thermoelectric material, wherein the thermoelectric material is configured to be electrically connected to a load.

27. A system, comprising:
a photovoltaic cell, comprising:
a photoactive material; and
a thermoelectric material; and
a load electrically connected to the thermoelectric material.

28. A photovoltaic cell, comprising:
a photoactive material; and
a thermoelectric material, provided that the thermoelectric material is not poly(3-hexylthiophene).

29. A photovoltaic cell, comprising:
a photoactive material; and
a thermoelectric material that is electrically isolated from the photoactive material.
